(19) United States
(12) Patent Application Publication
(10) Pub. No.: US 2013/0133734 A1
(43) Pub. Date: May 30, 2013

(54) PHOTOVOLTAIC CELL

(71) Applicants: Emmanuelle Peter, Aix-en-Provence (FR); Emilie Charlet, Paris (FR); Fraj Hamdi, Poissy (FR); Charles Leyder, Paris (FR)

(72) Inventors: Emmanuelle Peter, Aix-en-Provence (FR); Emilie Charlet, Paris (FR); Fraj Hamdi, Poissy (FR); Charles Leyder, Paris (FR)

(73) Assignee: SAINT-GOBAIN GLASS FRANCE, Courbevoie (FR)

(21) Appl. No.: 13/582,127

(22) PCT Filed: Feb. 28, 2011
(86) PCT No.: PCT/FR2011/050400

§ 371 Date: Feb. 13, 2013

(30) Foreign Application Priority Data
Mar. 1, 2010 (FR) 1051456

(51) Int. Cl. H01L 31/0224

(52) U.S. Cl. CPC H01L 31/022425
USPC 136/256

(57) ABSTRACT

A photovoltaic cell includes transparent glazing substrate, protecting a thin-film multilayer including a film having photovoltaic properties; and two films forming electrodes, one the bottom electrode film and the other the top electrode film, placed on either side of the photovoltaic film, the bottom electrode film being a TCO including a zinc oxide substituted by an element selected from Al, Ga, In, B, Ti, V, Y, Zr and Ge or any combination thereof. The cell includes, between the substrate and the bottom electrode film, a succession of at least two films of dielectric materials, including a first film of a material forming a barrier to the alkali metals coming from the glazing substrate, especially during a tempering or annealing operation; and a second film including aluminum nitride AlN, gallium nitride GaN or a mixture thereof, the second film being in contact with the bottom electrode film.

The invention relates to a novel photovoltaic cell, comprising a glazing substrate coated with a film of transparent conductive oxide, usually abbreviated to TCO in the field. In the rest of the description, the term “glazing substrate” is understood to mean a substrate made of a mineral glass.

As is known, a photovoltaic module consists of an assembly of photovoltaic cells, also called photovoltaic modules, often coupled in series to one another. These cells or modules generate a direct current when they are exposed to light. To deliver a suitable amount of power, corresponding to a sufficient and expected amount of energy, sufficiently extensive areas of a multitude of photovoltaic modules are produced. These modules may be incorporated into the roofs of dwellings or commercial properties or placed in fields for centralized energy production. Various technologies exist for producing photovoltaic cells. The most common cells incorporate, as photovoltaic photosensitive material, a combination of n-doped and p-doped semiconductors, in particular semiconductors based on crystalline silicon or thin-film semiconductors.

Conventionally, a photovoltaic module thus comprises a substrate serving as support and what is called the photovoltaic material, which usually consists of a stack of n-doped and p-doped semiconductors, forming a p-n junction in their electrical contact zone. Another substrate, on the opposite face, protects the photovoltaic material. Of these two substrates, the one intended to face the received light energy is referred to as the front substrate or front face substrate. This front face substrate is preferably a transparent mineral glass having a very high light transmission in the 300 to 1250 nm radiation range. It is advantageously heat-treated (i.e. annealed, tempered or toughened) in order to be able to withstand foul weather, in particular hail, over a long period of time (25 to 30 years). Placed on each side of the photovoltaic material are electrodes consisting of electrically conductive materials that constitute the positive and negative terminals of the photovoltaic cell. As is known, the two electrodes (anode and cathode) of the photovoltaic module serve to collect the current produced in the photovoltaic material under the effect of light, the transfer and segregation of the charges being due to the potential difference created between the respectively p-doped and n-doped portions of the semiconductors. An example of such a module is for example described in patent application WO 2006/005889 to which the reader may refer for construction details.

Although crystalline silicon as semiconductor offers good energy efficiency and constitutes the first generation of photovoltaic cells in the form of “wafers”, it is becoming increasingly advantageous in the industry to use what is called “thin-film” technology. According to this technology, the material acting as site for the photovoltaic activity, comprising or consisting of amorphous silicon (a-Si) or microcrystalline silicon (μc-Si), or even cadmium telluride (CdTe) or chalcopyrites (CIS, CIGS or CiGSe₂), is this time directly deposited on the substrate in the form of relatively thick films. However, the reduced thickness of these materials formed by thin-film deposition theoretically offers the possibility of reducing the production cost of the cells. The manufacture of modules on glazing substrates, cut to the final size of the modules, thus comprises the deposition of a succession of thin films deposited, and formed directly one after another, on the substrate, including at least:
a film serving as front electrode transparent to the incident radiation;
the various thin films constituting the photovoltaic material itself; and
a thin film serving as reflective back electrode.

The photovoltaic cells, as regards their cutting and the electrical connections to be established between them, are produced by intermediate laser etching steps between each thin-film deposition step. The often tempered glazing substrates incorporating the photovoltaic cells thus constitute the front face substrates of the modules. A back face support substrate is then attached by lamination to that face of the front face substrate which is provided with the thin-film multilayer.

The electrode placed against the glass front face substrate of the module is of course transparent in order to let the light energy pass through it to the photovoltaic active film. This electrode usually comprises a transparent electrically conductive oxide usually referred to in the field as a TCO (Transparent Conductive Oxide).

It is known to use, as material for the manufacture of these TCO films, thin films of aluminum-doped zinc oxide (AZO), indium-doped tin oxide (ITO), fluorine-doped tin oxide (SnO₂:F) or else gallium-doped zinc oxide (GZO) or boron-doped zinc oxide (BZO), without however this list being exhaustive.

It should be clearly noted that these films constituting the electrodes, especially those placed on the front face, i.e. close to the front substrate, are essential functional components of thin-film solar cells since they serve for collecting and removing the electrons or holes formed by the incident electromagnetic radiation in the photovoltaic semiconductor films. In this regard, it is necessary for the application for their resistivity to be as low as possible. In particular, in order to obtain the desired electrical conduction, or the desired low resistance, the TCO-based electrode coating must be deposited with a relatively large physical thickness of the order of a few hundred nanometers, incurring a high cost relative to the cost of the materials when they are deposited in thin-film form, especially using the magnetron sputtering technique. The major drawback of TCO-based electrode coatings thus lies most particularly in the fact that the physical thickness of the material is necessarily a compromise between its final electrical conduction and its final transparency after deposition. In other words, the greater the physical thickness of the material, the higher its conductivity but the lower its transparency, and vice-versa. In the end, it is not possible for current TCO coatings to be independently and satisfactorily optimized with regard to conductivity of the electrode coating and its transparency, especially its light absorption and its light transmission.

Another problem associated with these TCOs stems from their use in the specific application as electrode in a photovoltaic module: to give glazing substrates their mechanical strength, the substrates coated with the TCO film must often undergo a final heat treatment, especially a tempering treatment. Likewise, it is often necessary to heat the TCO film in order to increase the crystallinity thereof and consequently the conductivity and transparency. In addition, depositing certain photovoltaic films such as CdTe films requires a processing temperature of at least 400° C. and even up to 700° C. During successive heating and/or tempering steps, the multilayer is thus heated, in the ambient atmosphere or another atmosphere, to temperatures above 500° C., or even above 600° C., for a few minutes. Unfortunately, during these heat treatments, after a beneficial first phase in which their electrical resistivity (or their R/□) decreases, most TCOs see on the contrary their electrical properties drastically degraded, their electrical resistance increasing exponentially if the heat treatment is prolonged beyond a few minutes. Without this being able to be considered as a definitive assertion, such an effect could be explained on the one hand because of the migration of alkali metals from the glass via the surface of the TCO film facing the substrate and on the other hand by the oxidation of the TCO by the oxygen contained in the furnace through the other surface. Existing solutions, described for example in the patent applications WO 2007/018951 or US 2007/0029186, propose encapsulating the TCO in top and bottom barrier films, thus protecting it against the migration of alkali metals (via the underlayer) and from oxidation (via the overlayer). However, these barrier films, although they do moderate the degradation of the TCO during tempering, they do not improve it.

In the rest of the description and in the claims, the terms “bottom” and “top” denote the respective positions of the films relative to one another and with reference to the front face glazing substrate. Likewise, the term “overlayer” denotes a film placed above the electrode (TCO) film relative to the front face glazing substrate and the term “underlayer” denotes a film placed beneath the electrode (TCO) film relative to the front face glazing substrate.

In patent application WO 2009/056732, it has already been proposed also to place, in addition to this alkali-metal barrier underlayer and this oxidation-preventing overlayer an additional metallic film capable of being oxidized during the heat treatment.

The aim of the present invention is therefore to alleviate the drawbacks of the above techniques by providing a solution comprising a multilayer such that the properties, both optical and electrical conduction properties, of the TCO film are not substantially affected by the successive heat treatment and heating phases during manufacture of the photovoltaic cell, and are even improved by said phases.

The object of the present invention is more particularly to provide a novel photovoltaic cell comprising a transparent glazing substrate coated with a transparent electrically conductive oxide film TCO, the optical properties of which are improved, especially after an annealing operation for recrystallizing the TCO film.

More precisely, the present invention relates in the first place to a photovoltaic cell comprising at least one transparent glazing substrate, protecting a thin-film multilayer comprising at least:
a film having photovoltaic properties; and
two films forming electrodes, one the bottom electrode film and the other the top electrode film, placed on either side of said photovoltaic film,
   said bottom electrode film being a TCO comprising or consisting of a zinc oxide substituted in particular by an element chosen from the group comprising Al, Ga, In, B, Ti, V, Y, Zr and Ge or with a combination of these various elements,
   said cell being characterized in that it further includes, between said substrate and said bottom electrode film, a succession of at least two films of dielectric materials, comprising:
a first film or a set of first films of at least one material forming a barrier to the alkali metals coming from the glazing substrate, especially during a tempering or annealing operation; and
a second film comprising or consisting of aluminum nitride AlN, gallium nitride GaN or a mixture of the two compounds,
said second film, made of AlN or GaN or a mixture of these two compounds, being in contact with said bottom electrode film.

Preferably, the second film in contact with said bottom electrode film consists of aluminum nitride AlN.

The expression “of the substituted zinc oxide type” is understood to mean a zinc oxide substituted with an element of the periodic table, especially by doping, up to an amount enabling the electrical conductivity to be substantially increased thereby, according to principles well known in the field for obtaining TCOs.

In particular, the bottom electrode film may be a TCO comprising or consisting of zinc oxide ZnO doped with an element chosen from the group Al, Ga, In, B, Ti, V, Y, Zr and Ge or with a combination of these various dopants. This film is preferably a TCO consisting of zinc oxide ZnO doped with aluminum (AZO) or zinc oxide ZnO doped with gallium (GZO) or zinc oxide ZnO codoped with gallium and aluminum.

Typically, the material forming an alkali-metal barrier comprises at least one film of a material chosen from the group formed by Si₃N₄, SnₓZn_{y}O_{z}, SiO₂, SiOₓN_{y}, TiO₂ and Al₂O₃, said material optionally being doped in particular with an element chosen from Al, Zr and Sb.

In particular, the film forming an alkali-metal barrier may consist only of Si₃N₄.

According to one possible embodiment, the physical thickness of the film or films forming an alkali-metal barrier is, in total, between 15 and 100 nm, preferably between 20 and 80 nm.

The physical thickness of the film made of AlN, GaN or a mixture of the two compounds may be between 30 and 200 nm, preferably between 40 and 150 nm.

The thickness of the second film made of AlN, GaN or a mixture of the two is preferably greater than the physical thickness of the first film forming an alkali-metal barrier.

In particular, the ratio of the physical thickness of said second film made of AlN, GaN or a mixture of the two to that of the first film forming an alkali-metal barrier is between 1.1 and 20.0, preferably between 1.2 and 10.

The bottom electrode film may be covered on its other face by one or more oxidation protection films.

In a photovoltaic cell according to the invention, the photovoltaic film comprises or consists of semiconductor materials of the amorphous silicon (a-Si), microcrystalline silicon (μc-Si) or cadmium telluride (CdTe) type or else based on a thin-film assembly of amorphous silicon on microcrystalline silicon so as to make up a tandem cell.

The invention also relates to the transparent substrate as has just been described, capable especially of constituting the front face of a photovoltaic cell as described above, comprising, on one of its faces, a transparent coating consisting of a conductive metal oxide (TCO) as described above and further including, between said substrate and said TCO film, a succession of at least two films of dielectric materials, including a first film or a set of first films of at least one material forming a barrier to alkali metals coming from the glazing substrate, especially while said substrate is being tempered or annealed, and a second film comprising or consisting of aluminum nitride AlN, gallium nitride GaN or a mixture of the two compounds, said film made of AlN, GaN or a mixture of the two compounds being in contact with said conductive metal oxide TCO.

Of course, in such a transparent substrate, such as that described above:
the film forming an alkali-metal barrier may consist exclusively of Si₃N₄;
the second film in contact with said TCO film may consist of aluminum nitride AlN; and
the TCO may comprise or consist of aluminum-doped zinc oxide AZO.

One embodiment of the present invention will be described below without this being able to be considered as limiting the present invention, according to any of the aspects described, in relation to the single appended FIGURE.

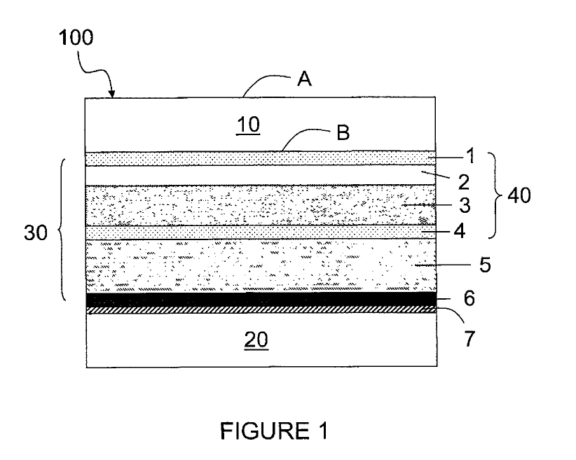

FIG. 1 shows schematically a photovoltaic cell 100 according to the present invention.

This cell comprises, as front face, i.e. on the side exposed to the solar radiation, a transparent first glazing substrate 10, namely the front face substrate. This substrate may for example be made entirely of a glass containing alkali metals, such as a soda-lime-silica glass.

Nearly all the mass (i.e. at least 98% by weight) or indeed all of the substrate having a glazing function preferably consists of material(s) having the best possible transparency to the radiation in that part of the solar spectrum useful for the application as a solar module, i.e. generally that part of the spectrum ranging from about 300 to about 1250 or 1300 nm. Thus, the transparent substrate 10 chosen according to the invention has a high transmission for electromagnetic radiation with a wavelength of 300 to 1300 nm and in particular for solar light. In general, the glazing substrate is chosen such that its transmission, within said range, is greater than 75% and in particular greater than 85% or even greater than 95%. Advantageously, this substrate is an extra-clear glass, such as the glass Diamante® sold by Saint-Gobain, or a surface-textured glass, such as the glass Albarino®, again sold by Saint-Gobain.

The substrate may have a total thickness ranging from 0.5 to 10 mm and is used in particular as protective plate for a photovoltaic cell. For this purpose, it may be advantageous for it to undergo beforehand a heat treatment, such as a tempering treatment.

Conventionally, the front face of the substrate 10 directed toward the light rays (the external face) is called face A, and the rear face of the substrate directed toward the rest of the films of the solar module (internal face) is called face B.

Face B of the substrate 10 is coated with a thin-film multilayer 30 using the methods of the invention.

Thus, at least one surface portion of the substrate is coated on its face B with at least one film 1 of a material known for its barrier properties, preventing diffusion of alkali metals through the various films of the multilayer 30, in particular when the assembly is heated to high temperature, for example during the various tempering or annealing phases or else during hot deposition, being essential during the course of the cell manufacturing cycle. The presence of this barrier film 1 on face B of the substrate makes it possible in particular to avoid or even block the diffusion of sodium from the glass into the upper active films.

According to the invention, the nature of this barrier film is not particularly limited and any film known for this purpose may be used. This alkali-metal barrier film may especially be based on a dielectric material, chosen from silicon nitrides, oxides or oxynitrides or else zirconium nitrides, oxides or oxynitrides. It may especially be Si₃N₄, SnₓZn_{y}O_{z}, SiO₂, SiOₓN_{y} or TiO₂. Among all these materials, silicon nitride Si₃N₄ in particular provides an excellent alkali-metal barrier effect. This alkali-metal barrier film, especially when it is based on silicon nitride, need not be stoichiometric: it may be by nature substoichiometric or superstoichiometric.

However, the film 1 is not necessarily a single film, and it is envisioned in the context of the present invention to replace it with a combination of films having this same purpose of acting as a barrier to alkali metals. The thickness of the barrier film 1 (or of the combination of barrier films) is in total between 3 and 200 nm, preferably between 10 and 100 nm and especially between 20 and 50 nm.

According to the invention, a second film 2 is deposited on this alkali-metal barrier first film, said second film comprising and preferably consisting of a material chosen from aluminum nitride AlN, gallium nitride GaN or a mixture of these two compounds. The film 2 may in particular consist exclusively of aluminum nitride AlN.

An electrically conductive film 3 of the TCO type is deposited according to the invention on this second film 2 and directly in contact therewith. This film 3 constitutes the bottom electrode of the photovoltaic cell. The film 3 preferably consists of a material chosen from zinc oxides doped or substituted with at least one element of the group: Al, Ga. As a variant, it is also possible to choose a dopant or substituent element chosen from In, B, Ti, V, Y and Zr.

The conducting film 3 must be as transparent as possible and have a high light transmission within the range of wavelengths corresponding to the absorption spectrum of the material constituting the functional film, so as not to reduce the efficiency of the solar module unnecessarily. The thickness of this electrically conductive film is between 50 and 1500 nm, preferably between 200 and 800 nm and substantially around 700 nm. The TCO film of the substrates according to the invention must have a high electrical conductivity and a high transparency to electromagnetic radiation and in particular to solar light.

The electrically conductive TCO film 3 according to the invention must have a sheet resistance of at most 30 ohms/□, especially at most 20 ohms/□ or even at most 10 ohms/□ in the photovoltaic module.

According to the invention, at least the transparent electrically conductive TCO film and preferably at least the films 1 to 3 of the multilayer 30 are deposited, especially in succession and in the same apparatus, by known thin-film vacuum deposition techniques, in particular by sputtering techniques commonplace in the field of thin-film deposition, in particular magnetron sputtering techniques, as will be explained in greater detail below.

According to one possible embodiment, the surface of the transparent electrically conductive film may be textured, the RMS roughness of which texture is between 1 nm and 250 nm, especially if the photovoltaic film 5 of the cell 10 is based on silicon. The roughness of the film 3 is then preferably between about 20 nm and about 180 nm, and particularly preferably between 40 nm and 140 nm. The size of the texturing may be determined for example by scanning electron microscopy (SEM) or by atomic force microscopy (AFM). The RMS (root mean square) roughness is for example determined according to the ISO 25178 standard using an atomic force microscope.

According to one possible embodiment of the invention, which is however not obligatory, the electrically conductive film serving as bottom electrode may then be covered with an oxidation protection film 4.

According to one possible embodiment of the invention, such as that described in patent application WO 2009/056732, it is also conceivable to incorporate into the multilayer, above the bottom electrode 3, at least one metallic blocking film which will be able to be oxidized, that is to say capable of creating a film of oxide of the metal in question during the heat treatment of the bottom electrode, more precisely for example while the substrate coated with said electrode is being tempered or annealed. The metallic blocking film may be based on titanium, nickel, chromium or niobium, used individually or as an alloy.

The primary thin-film multilayer 40 thus formed on the front face substrate 10 is covered with a functional film 5 comprising energy-conversion materials, the light rays being converted to electrical energy, as described above.

Examples of semiconductor materials having photovoltaic properties that are suitable for being used as the thin film 5 in the solar cells according to the invention are for example, without being restrictive, amorphous silicon (a-Si), microcrystalline silicon (μc-Si), polycrystalline silicon (pc-Si), gallium arsenide (as a monolayer), gallium arsenide (as two films), gallium arsenide (as three films), gallium indium nitride, cadmium telluride and copper-indium-(gallium)-sulfur-selenium compounds.

The photovoltaic semiconductor film of the thin-film solar cells according to the invention may use a single semiconductor transition (simple junction) or several semiconductor transitions (multijunction). Semiconductor films having the same inter-band transition may use only a portion of the solar light, whereas semiconductor films having different inter-band transitions are sensitive to a larger portion of the solar spectrum.

To form the second, top electrode, the functional film 5 is covered with an optionally transparent conductive film 6, of TCO type as described above, or of nontransparent type, such as for example a film of molybdenum or of another metallic material. In particular, the top electrode film may be based on ITO (indium tin oxide) or made of a metal (silver, gold, copper, aluminum or molybdenum) or made of a fluorine-doped tin oxide or an Al-doped zinc oxide.

The combination of thin films 1-6 of the multilayer 30 is finally sandwiched between the front face substrate and a rear face substrate 20 in the form of a laminated structure by means of a thermoplastic interlayer 7, for example made of PU, PVB or EVA, so as to form the final solar cell 100.

The photovoltaic cell according to the invention, such as that which has just been described, may be obtained using a process comprising the following steps:
a) the surface of the front face substrate 10 is coated, in succession and in the same device, by the thin-film multilayer 40 comprising the transparent electrically conductive oxide film and its protective coatings using the vacuum deposition technique of sputtering, possibly magnetron sputtering;
b) the coated substrate is heated between 300° C. and 750° C. in an atmosphere containing oxygen for example, so as to crystallize the TCO film;
c) optionally, the transparent electrically conductive oxide film is etched;
d) the photovoltaic film 5 is deposited, again possibly using the vacuum technique and in the same device;
e) the bottom electrode film 6 is deposited; and
f) the final thin-film multilayer 30 is encapsulated between the front face substrate 10 and the rear face substrate 20 by applying a thermoplastic polymer 7 so as to obtain a laminated structure.

Step a), comprising vacuum deposition by sputtering, is a known conventional process for producing thin films of materials that are difficult to vaporize. The surface of a solid body of appropriate composition, called a target, is sputtered by firing high-energy ions coming from a low-pressure plasma, for example oxygen ions (O⁺) and/or argon ions (Ar⁺) or neutral particles, after which the sputtered materials are deposited as thin films on the substrates (see Römpp Online, 2008, “Sputtering”). It is preferred to use sputtering maintained by a magnetic field, usually called magnetron sputtering. According to the invention, the oxygen or argon partial pressure may vary widely and thus be easily adapted according to the requirements of each particular case. For example, the partial pressure levels of the gases in the plasma and the electrical power needed for sputtering may be defined according to the dimensions of the transparent substrates and the thickness of the films (particularly the TCO films) to be deposited.

In the process according to the invention, the films are sputtered in succession in continuous plants, already accordingly sized, by means of appropriate sputtering targets. According to the invention it is preferred to use a target having a composition corresponding substantially, or even precisely, to that of the TCO film finally obtained on the substrate. In this case, it is advantageously possible to use the technique of sputtering sustained through the action of a magnetic field, usually called magnetron sputtering. The drawback of such devices is however the fact that the films obtained have a low degree of crystallinity of the constituent materials, especially that of the TCOs, and therefore require an annealing step in order to recrystallize said materials.

Step b) is therefore a step of paramount importance for the final performance of the photovoltaic cell and in particular determines its final efficiency. In this step, the coated substrate of the multilayer 40 is heated between 300° C. and 750° C., preferably between 500° C. and 700° C. and in particular between 600° C. and 700° C. in various atmospheres, and for example in an oxygen-containing atmosphere. As oxygen-containing atmosphere it is possible to use air or a gas mixture having an oxygen content below or above that of air. The treatment step may be carried out by means of standard known devices, for example the furnaces normally used in the glass industry (tempering furnace) through which a glass ribbon of appropriate size runs continuously. These continuous furnaces normally use air or an inert gas as heat-transfer fluid. By virtue of this heat treatment b) of the coated and heated substrate, the oxide film is thus made crystalline and its resistivity therefore greatly decreases. Thus, the TCO film according to the invention described above is obtained.

The transparent substrates covered with the TCO film are cooled, preferably before the next treatment step c) is carried out, for example by streams of cold air or cold inert gases, but it is also possible to let them cool down passively. After cooling, the coated substrate preferably has a temperature of 20° C. to 30° C. In this way, the risk of damaging the substrates by thermal stresses and/or the risk of uncontrolled evaporation or decomposition of the liquids that are brought into contact with the coated substrates during, or possibly before, the following treatment step c) are reduced or even completely eliminated.

The transparent electrically conductive oxide film may be etched by means of an etchant, and the etchant is then rinsed off. The etchants may be gaseous or liquid—they are preferably liquids. The liquid etchants may contain liquid organic compounds, liquid mineral compounds, solutions of solid, liquid or gaseous organic or mineral compounds in organic solvents, and also aqueous solutions of solid, liquid or gaseous organic or mineral compounds. It is preferred to use aqueous solutions of acids or bases of organic or mineral origin. Preferably, volatile organic or mineral acids, particularly mineral acids, are used.

The substrate bearing the transparent TCO electrode may also be manufactured and possibly etched independently of the other constituent elements of the module so as to be delivered to an assembler possessing the technology for depositing semiconductor materials but are responsible for the actual photovoltaic activity.

The bottom electrode 6, i.e. that turned toward the interior of the cell relative to the incident radiation, preferably reflects said radiation. It is deposited (step e)) in a known manner, especially using a vacuum deposition technique.

Finally, during step f) the rear face substrate 20 is laminated to the assembly by means of a plastic film 16 of the polyvinyl butyral (PVB) or ethylene-vinyl acetate (EVA) type using well-known techniques for obtaining laminated glazing.

### EXAMPLES

The following examples serve to illustrate the advantages and the improved properties of the embodiments according to the invention. These examples must in no case be considered, according to any of the aspects described, as limiting the scope of the present invention.

Firstly, successive films were deposited on a Diamant® glass sold by Saint-Gobain using the well-known technique of magnetron vacuum deposition under the usual conditions for obtaining a substrate provided with a first TCO film (bottom electrode of the cell). Several specimens were prepared, certain multilayers being in accordance with the invention (Examples 4 and 5) and others not in accordance with the invention (Example 6) or according to the prior art (Examples 1 to 3). More precisely, Examples 1 to 3 comprise only one alkali-metal barrier film between the substrate and the TCO film. Examples 4 and 5, in accordance with the invention, comprise a succession of two films: a silicon nitride first film 1 acting as alkali-metal barrier and an aluminum nitride (AlN) second film 2. The silicon nitride film was obtained in a known manner using a silicon target containing 8 percent aluminum, this being sputtered in a nitrogen atmosphere (reactive sputtering).

Another, comparative multilayer was prepared according to Example 6, also comprising two protection films but not in accordance with the invention.

Table 1 below indicates in greater detail the compositions of the various multilayers prepared and their physical (actual) thicknesses.

TABLE 1

| | | Film 1 | Film 2 | |
|---|---|---|---|---|
| | | (alkali- | (according | |
| | Glazing | metal | to the | Film 3 |
| Specimen | substrate | barrier) | invention) | (TCO) |
| Example 1 | Diamant ® | Si₃N₄ | — | AZO (ZnO: Al 1%)* |
| | | 200 nm | | 800 nm |
| Example 2 | Diamant ® | Si₃N₄ | — | AZO (ZnO: Al 1%)* |
| | | 50 nm | | 800 nm |
| Example 3 | Diamant ® | AlN | — | AZO (ZnO: Al 1%)* |
| | | 60 nm | | 800 nm |
| Example 4 | Diamant ® | Si₃N₄ | AlN | AZO (ZnO: Al 1%)* |
| | | 50 nm | 60 nm | 800 nm |
| Example 5 | Diamant ® | Si₃N₄ | AlN | AZO (ZnO: Al 1%)* |
| | | 50 nm | 100 nm | 800 nm |
| Example 6 | Diamant ® | Si₃N₄ | SiO₂ | AZO (ZnO: Al 1%)* |
| | | 50 nm | 60 nm | 800 nm |

*ZnO doped with 1% Al as a percentage by weight of Al₂O₃ with respect to the total weight of the oxides.

The variations in sheet resistance of the various TCO films of the substrates of Examples 1, 2 and 5 (according to the invention) and the light transmission T_{L} of said substrates (on the film side) were measured before and after annealing at 550° C. for 5 and 9 minutes of baking respectively. The sheet resistance of the TCO films was measured by conventional techniques, using the four-point method or Van der Pauw method. The T_{L} measurements were carried out under illuminant D65 over a wavelength range between 300 and 2500 nm on a Perkin Elmer Lambda 900 spectrometer. The results are given in Table 2.

TABLE 2

| | | 5 min. anneal | | 9 min. anneal | |
|---|---|---|---|---|---|
| Specimen | Multilayer | □(R/_{□}) | □T_{L} | □(R/_{□}) | □T_{L} |
| Example 1 | glass/Si₃N₄ (200 nm)/AZO | −8 | 5.9 | 87 | 8.6 |
| Example 2 | glass/Si₃N₄ (50 nm)/AZO | −10 | 7.6 | 90 | 9.7 |
| Example 3 | glass/AlN (60 nm)/AZO | −8.3 | 6.6 | 163 | 9.2 |
| Example 4 | glass/Si₃N₄ (50 nm)/AlN | −7.8 | 8.5 | 34.6 | 11 |
| | (60 nm)/AZO | | | | |
| Example 5 | glass/Si₃N₄ (50 nm)/AlN | −7 | 7.6 | −7 | 11.5 |
| | (100 nm)/AZO | | | | |
| Example 6 | glass/Si₃N₄ (50 nm)/SiO₂ | −5.2 | 8.9 | 120 | 9.6 |
| | (60 nm)/AZO | | | | |

This table shows that the resistivity properties according to Examples 1 and 2 are relatively similar, thereby indicating that a thickness of 50 nm of the Si₃N₄ film is sufficient for acting effectively as barrier to the alkali metals coming from the glazing substrate. It may also be seen, by comparing the data given in Table 2, that there is a significant difference in behavior between the multilayers of Examples 1 to 3 according to the prior art, the multilayer of Comparative Example 6 and the multilayers of Examples 4 and 5 according to the invention: in the case of annealing for 9 minutes under the same conditions, the TCO films according to Examples 1 to 3 and 6 show much higher variations in their sheet resistance than those of the TCO films incorporated into the multilayers of Examples 4 and 5 in accordance with the invention.

It is thus possible by virtue of substrates incorporating the multilayer according to the invention for the duration of annealing to be significantly extended without appreciably degrading the properties, especially conducting properties, of the TCO film.

Furthermore, compared with other configurations illustrated by Example 6, it is also apparent that such an improvement effect is obtained only by the specific combination according to the invention, i.e. the combination of a first film of a material known to form a barrier to alkali metals coming from the glazing substrate and a second film formed by aluminum nitride AlN, said AlN film being placed directly in contact with the TCO film in the cell.

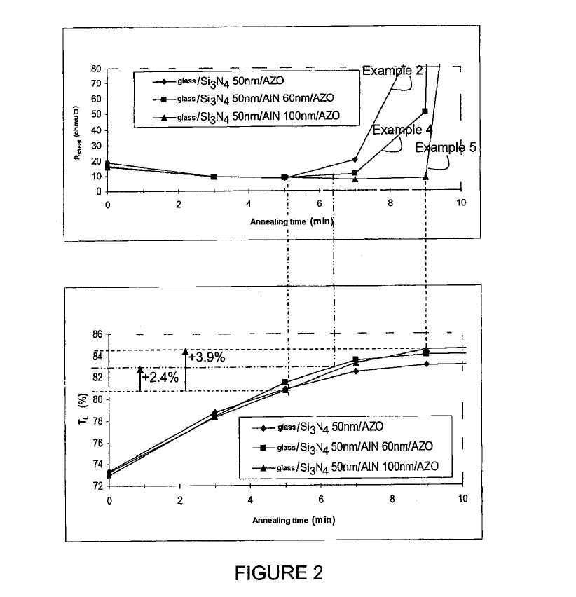

Secondly, the change in sheet resistance as a function of the duration of the annealing step at 550° C. was also measured on the substrates according to Example 2, according to the prior art and Examples 4 and 5 according to the invention. The results obtained may be seen in Table 3 and in FIG. 2. The annealing was extended for each of the substrates until reaching the maximum possible duration of the heat treatment relative to a maximum target value of 10 ohms/□ representative of acceptable conductivity in the cell of the TCO films for the photovoltaic application. For each of the substrates of Examples 2, 4 and 5, the light transmission T_{L} and the light reflection R_{L} under the same conditions as described previously were also measured. Again, the results obtained may be seen in FIG. 2.

TABLE 3

| | | | | after annealing | | after annealing | |
|---|---|---|---|---|---|---|---|
| | | unannealed | | (3 min. at 550° C.) | | (5 min. at 550° C.) | |
| Example | Multilayer | R/□ | T_{L} | R/□ | T_{L} | R/□ | T_{L} |
| Example 2 | Si₂N₄ (50 nm)/AZO | 19 | 73.3 | 9.5 | 78.8 | 8.2 | 80.9 |
| Example 5 | Si₃N₄ (50 nm)/AlN (60 nm)/AZO | 16.4 | 73 | 9.3 | 78.4 | 8.6 | 81.5 |
| Example 4 | Si₃N₄ (50 nm)/AlN (100 nm)/AZO | 15.8 | 73.2 | 9.4 | 78.3 | 8.8 | 80.8 |
| | | after annealing | | after annealing | | after annealing | |
| | | (7 min. at 550° C.) | | (9 min. at 550° C.) | | (15 min. at 550° C.) | |
| Example | Multilayer | R/□ | T_{L} | R/□ | T_{L} | R/□ | T_{L} |
| Example 2 | Si₃N₄ (50 nm)/AZO | 19.8 | 82.5 | 109.1 | 83.1 | insulating | 83.4 |
| Example 5 | Si₃N₄ (50 nm)/AlN (60 nm)/AZO | 11.2 | 83.5 | 51 | 84.1 | | |
| Example 4 | Si₃N₄ (50 nm)/AlN (100 nm)/AZO | 7.32 | 83.3 | 8.5 | 84.5 | 1119 | 85 |

The results given in Table 3 and in FIG. 2 clearly show the advantages of the embodiments according to the invention. Thus, for the same sheet resistance of 10 ohms/□, the substrate according to the prior art has a T_{L} of about 81.3%, whereas the substrates according to the invention for which the heat treatment could be maintained for a longer time, has substantially higher T_{L} values, namely 83.2% (+2.4%) in the case of the substrate according to Example 4 and 84.5% (+3.9%) in the case of the substrate according to Example 5, respectively.

The absorption A_{L} (where A_{L}(%)=100−T_{L}(%)−R_{L}(%)) and the parameter AsQE of the substrates according to Examples 2 and 5 were also determined, the TCO films of which were annealed and recrystallized so as to have an identical sheet resistance equal to 10 ohms/□. More particularly, the method consists in determining the parameter AsQE obtained by multiplying the absorption spectrum of the substrate comprising the TCO film integrated over the entire (300-2500 micron) range in question by the quantum efficiency QE spectrum of the material in question (i.e. a-Si, CdTe or a-Si/μc-SiC tandem) for this same range.

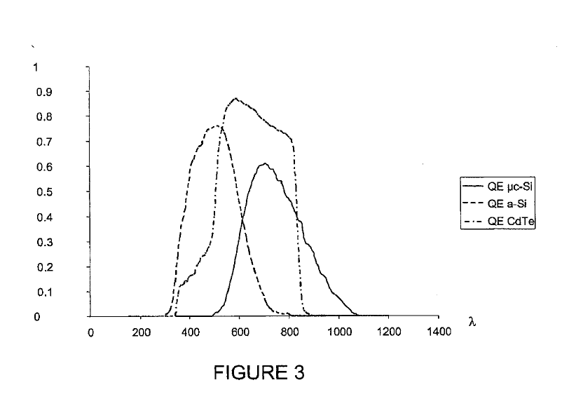

It will be recalled that the quantum efficiency QE is, as is known, the expression of the probability (between 0 and 1) that an incident photon of a wavelength as abscissa is converted into an electron-hole pair for the photovoltaic material in question. The quantum efficiency (QE) curve of said materials is plotted in FIG. 3.

Table 4 below shows the values obtained for the light absorption (A_{L}) and the parameter AsQE thus obtained for various cells comprising various types of photovoltaic films covered on the front face with the substrates according to Examples 2 and 5.

TABLE 4

| Front face | | AsQE (%) with photovoltaic film: | | |
|---|---|---|---|---|
| substrate | Light absorption | | a-Si/μc-Si | |
| according to: | A_{L} (%) | a-Si | tandem | CdTe |
| Example 2 | 5.5 | 7.3 | 9 | 8.1 |
| Example 5 | 2.3 | 3.4 | 3.7 | 3.1 |

It may be seen from the data given in Table 4 above that the performance of photovoltaic cells provided with a front face substrate according to the invention is expected to be substantially superior to that of photovoltaic cells according to the prior art.

1. A photovoltaic cell comprising:
a transparent glazing substrate, protecting a thin-film multilayer comprising
a film having photovoltaic properties; and
two films forming electrodes, one a bottom electrode film and the other a top electrode film, placed on either side of said photovoltaic film,
said bottom electrode film being a transparent conductive oxide (TCO) comprising or consisting of a zinc oxide substituted by an element selected from the group consisting of Al, Ga, In, B, Ti, V, Y, Zr and Ge or any combination thereof, and,
between said substrate and said bottom electrode film, a succession of at least two films of dielectric materials, comprising:
a first film or a set of first films of at least one material forming a barrier to alkali metals coming from the glazing substrate; and
a second film comprising or consisting of aluminum nitride AlN, gallium nitride GaN or any mixture thereof,
said second film, made of AlN or GaN or any mixture thereof, being in contact with said bottom electrode film.

2. The cell as claimed in claim 1, wherein the second film in contact with said bottom electrode film is made of aluminum nitride AlN.

3. The cell as claimed in claim 1, wherein said bottom electrode film is a TCO comprising or consisting of zinc oxide ZnO doped with an element selected from the group consisting of Al, Ga, In, B, Ti, V, Y, Zr and Ge or any combination thereof.

4. The cell as claimed in claim 1, wherein the material forming an alkali-metal barrier comprises a film of a material selected from the group consisting of Si₃N₄, SnₓZn_{y}O_{z}, SiO₂, SiOₓN_{y}, TiO₂ and Al₂O₃, said material optionally being doped with an element chosen from Al, Zr and Sb.

5. The cell as claimed in claim 1, wherein the film forming an alkali-metal barrier consists of Si₃N₄.

6. The cell as claimed in claim 1, wherein a physical thickness of the film or films forming an alkali-metal barrier is, in total, between 15 and 100 nm.

7. The cell as claimed in claim 1, wherein a physical thickness of the film made of AlN, GaN or any mixture thereof is between 30 and 200 nm.

8. The cell as claimed in claim 1, wherein a thickness of the second film made of AlN, GaN or any mixture thereof is greater than the physical thickness of the first film forming an alkali-metal barrier.

9. The cell as claimed in claim 8, wherein a ratio of the physical thickness of said second film made of AlN, GaN or any mixture thereof to that of the first film forming an alkali-metal barrier is between 1.1 and 20.0.

10. The cell as claimed in claim 1, wherein the bottom electrode film is covered on the other face thereof by one or more oxidation protection films.

11. The cell as claimed in claim 1, wherein the photovoltaic film comprises or consists of semiconductor materials of amorphous silicon (a-Si), microcrystalline silicon (μc-Si) or cadmium telluride (CdTe) type or based on a thin-film assembly of amorphous silicon on microcrystalline silicon so as to make up a tandem cell.

12. A transparent substrate arranged to constitute a face of a photovoltaic cell as claimed in claim 1, comprising, on a face thereof, a transparent coating consisting of a transparent conductive oxide (TCO) film and, between said substrate and said TCO film, a succession of at least two films of dielectric materials, including a first film or a set of first films a material forming a barrier to alkali metals coming from the glazing substrate, and a second film comprising or consisting of aluminum nitride AlN, gallium nitride GaN or any mixture thereof, said film made of AlN, GaN or any mixture thereof being in contact with said transparent conductive oxide TCO.

13. The transparent glazing substrate as claimed in claim 12, wherein the film forming an alkali-metal barrier consists of Si₃N₄.

14. The transparent substrate as claimed in claim 12, wherein the second film in contact with said TCO film consists of aluminum nitride AlN.

15. The transparent substrate as claimed in claim 12, wherein the TCO comprises or consists of zinc oxide ZnO doped with aluminum (AZO) or zinc oxide ZnO doped with gallium (GZO) or zinc oxide ZnO codoped with aluminum and gallium.

16. The cell as claimed in claim 1, wherein the first film or set of first films is configured to form a barrier to the alkali metals coming from the glazing substrate during a tempering or annealing operation.

17. The cell as claimed in claim 3, wherein the TCO consists of zinc oxide ZnO doped with aluminum (AZO) or zinc oxide ZnO doped with gallium (GZO) or zinc oxide ZnO codoped with gallium and aluminum.

18. The cell as claimed in claim 6, wherein the physical thickness of the film or films forming the alkali-metal barrier is, in total, between 20 and 80 nm.

19. The cell as claimed in claim 7, wherein the physical thickness of the film made of AlN, GaN or any mixture thereof is between 40 and 150 nm.

20. The cell as claimed in claim 9, wherein the ratio is between 1.2 and 10.

21. A photovoltaic cell comprising:
a transparent glazing substrate;
a layer having photovoltaic properties;
a first electrode layer forming a first electrode of the cell and a second electrode layer forming a second electrode of the cell, the layer having photovoltaic properties arranged between said first electrode layer and said second electrode layer, said first electrode layer being a transparent conductive oxide comprising a zinc oxide substituted by an element selected from the group consisting of Al, Ga, In, B, Ti, V, Y, Zr and Ge or any combination thereof,
a first layer comprising a material forming a barrier to alkali metals coming from the glazing substrate;
a second layer comprising aluminum nitride AlN, gallium nitride GaN or any mixture thereof;
wherein the first layer and the second layer are arranged between said substrate and said first electrode layer, and
wherein said second layer is in contact with said first electrode layer.

22. A transparent substrate arranged to form a face of a photovoltaic cell, the substrate bearing over a face thereof a structure comprising:
a transparent conductive oxide layer comprising a zinc oxide substituted by an element selected from the group consisting of Al, Ga, In, B, Ti, V, Y, Zr and Ge or any combination thereof,
a first layer comprising a material forming a barrier to alkali metals coming from the glazing substrate;
a second layer comprising aluminum nitride AlN, gallium nitride GaN or any mixture thereof;
wherein the first layer and the second layer are arranged between said substrate and said transparent conductive oxide layer, and
wherein said second layer is in contact with said transparent conductive oxide layer.
